(19) United States
(12) Patent Application Publication
(10) Pub. No.: US 2002/0063331 A1
(43) Pub. Date: May 30, 2002

(54) FILM CARRIER SEMICONDUCTOR DEVICE

(76) Inventor: HIROKAZU HONDA, TOKYO (JP)

Correspondence Address: YOUNG & THOMPSON, 745 SOUTH 23RD STREET 2ND FLOOR, ARLINGTON, VA, 22202

(21) Appl. No.: 09/571,734

(22) Filed: May 15, 2000

(30) Foreign Application Priority Data
May 14, 1999 (JP) 11-134893

(51) Int. Cl. H01L 23/495; H01L 23/52; H01L 29/40

(52) U.S. Cl. 257/737; 257/668; 257/676; 257/692; 257/691; 257/778

(57) ABSTRACT

The present invention provides a film carrier semiconductor device comprising: an insulative base film; inner leads provided on a first surface of the insulative base film; a signal interconnection pattern provided on the first surface of the insulative base film; a ground plane provided on a second surface of the insulative base film; a conductive supporting plate fixed by a conductor to the first surface of the insulative base film, wherein the conductive supporting plate serves as a power voltage plane.

### BACKGROUND OF THE INVENTION

The present invention relates to a film carrier semiconductor device utilizing a tape automated bonding for a tape ball grid array, and more particularly to a film carrier semiconductor device suitable for a high speed performance with a reduced inductance of an interconnection of a power source system.

In recent years, the high integration of the semiconductor integrated circuit has been progressed with scaling down and increase in the number of pins. As a multiple pin package mounted thereon with the highly integrated semiconductor device, a ball grid array package has been developed which is responsible for narrowing inner lead pitch by utilizing the tape automated bonding.

In the ball grid array semiconductor device, similarly to a chip-on-board, an integration circuit chip is wire-boned and then molded before the chip is directly bonded onto solder bumps on a bottom surface of a printed board. The ball grid array comprises a two-dimensional array of connection terminals. This two dimensional ball grid array is suitable for realizing multiple pins and also is superior in electric characteristics. The two dimensional ball grid array is suitable for a low cost package.

The tape ball grid array is one of he ball grid array packages. The tape ball grid array comprises a two dimensional array of solder balls for external connections on signal interconnections of the tape automated bonding tape, wherein the signal interconnections are connected to electrodes on the semiconductor device. This tape ball grid array is more superior than the other ball grid arrays in the mass productivity and the formability.

FIG. 1 is a fragmentary cross sectional elevation view illustrative of a conventional film carrier semiconductor device using a conventional tape ball grid array. This conventional film carrier semiconductor device using a conventional tape ball grid array is also disclosed in Japanese laid-open patent publication No. 10-303339. An insulative base film 21 comprises a polyimide. A plurality of inner leads 22 are formed on the insulative base film 21. The inner leads 22 extend over a device hole 24 of the base film 24. Inner edges of the inner leads 22 over the device hole 24 are connected to electrodes provided on an LSI chip 23. The inner leads 22 extend on a front surface of the base film 21. Interconnection patterns 25a comprising metal thin films and a ground plane 25b comprising a metal tin film are formed on each of the front and back surfaces of the base film 21. Solder resist films 26a and 26b comprising thermo-setting resin such as an epoxy resin are formed around the same.

One having the ground potential of the inner leads 22 is connected to the ground plane 25b through a fine via hole 29 provided in the base film 21 and positioned near the device hole 24. Power source and signal leads are connected through the interconnection patterns 25a to a land portion for formation of the external terminals provided on the base film 21 and separated from the device hole 24.

An outer lead bonding portion is formed on the same surface of the base film 21, on which the ground plane 25b is formed. The lad portion and the outer lead bonding portion are connected through the through hole 27 formed in the insulative base film 21. A tape automated bonding or a tape ball grid array film carrier tape 30 comprises double metal layers.

On the outer lead bonding portion of the insulative base film 21, power source system solder balls 28 are provided as external terminals connected to the multilayer printed wiring board. The solder balls 28 are connected to the through holes 27. Further, power source system solder balls and signal system solder balls are also provided.

On the solder resist film 6a in a side of the interconnection pattern 25a of the tape automated bonding tape 30, a reinforcement plate 32 is fixed by an insulative adhesive agent 35. Bottom surfaces of the LSI chip 23 and the reinforcement plate 32 are fixed by an insulative adhesive agent 39 to a heat spreader 36. The LSI chip 23 and the inner leads 22 are coated by an insulative resin 38. The above conventional film carrier semiconductor device is inferior in heat radiation and also causes a stress concentration to the bonding parts.

A conventional method of forming a tape ball grid array package with a low heat resistance for a heat radiation from the chip is disclosed in Japanese laid-open patent publication No. 9-32645. In the conventional method, a semiconductor chip is mounted on a reinforcement plate or in an opening formed in the reinforcement plate and also a heat sink is provided on the reinforcement plate to reduce the heat resistance.

In Japanese laid-open patent publication No. 10-223698, it is disclosed that the tape ball grid array semiconductor device is improved in mounting on the board. FIG. 2 is a conventional tape ball grid array semiconductor device. On a thermally stable insulative resin film 38, signal interconnections are provided. Top portions of the signal interconnections are electrically connected to electrodes of the semiconductor device 39. The semiconductor device is protected by a sealing resin 44. A reinforcement plate 40 is fixed to a surface by the thermally stable insulative resin film 38 by an adhesive layer 41. The reinforcement plate 40 has an opening portion for mounting the semiconductor device 39. Solder balls 42 are mounted on external connecting portions of the signal interconnections. Slits 43 are provided along the opening of the reinforcement plate. This slits 43 relax the stresses generated by a difference in thermal expansion coefficient between the reinforcement plate 40 and the mounting substrate.

The conventional tape ball grid array package comprises double metal layers and has a micro-strip line structure provide with a ground plane through interconnection layer and insulative layer. An inductance is too large for high speed device with an operable frequency in the range of 300 MHz and 400 HMz. Namely, the above conventional package is not applicable to the high speed device.

In the above circumstances, it had been required to develop a novel film carrier semiconductor device free from the above problem.

### SUMMARY OF THE INVENTION

Accordingly, it is an object of the present invention to provide a novel film carrier semiconductor device free from the above problems.

It is a further object of the present invention to provide a novel film carrier semiconductor device with a reduced inductance of a power source system.

It is a still further object of the present invention to provide a novel film carrier semiconductor device suitable for a high speed device.

The present invention provides a film carrier semiconductor device comprising: an insulative base film; inner leads provided on a first surface of the insulative base film; a signal interconnection pattern provided on the first surface of the insulative base film; a ground plane provided on a second surface of the insulative base film; a conductive supporting plate fixed by a conductor to the first surface of the insulative base film, wherein the conductive supporting plate serves as a power voltage plane.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIG. 1 is a fragmentary cross sectional elevation view illustrative of a conventional film carrier semiconductor device using a conventional tape ball grid array.

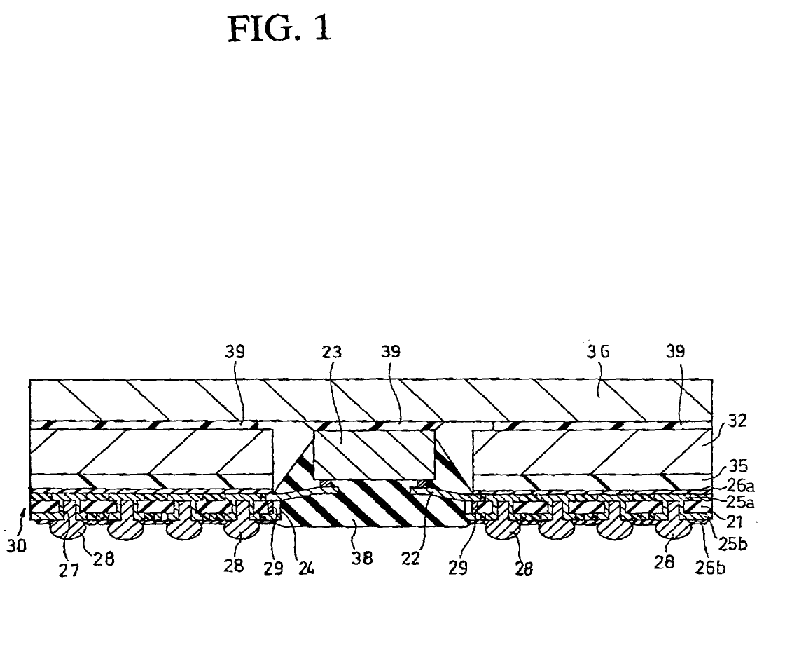

FIG. 2 is a conventional tape ball grid array semiconductor device.

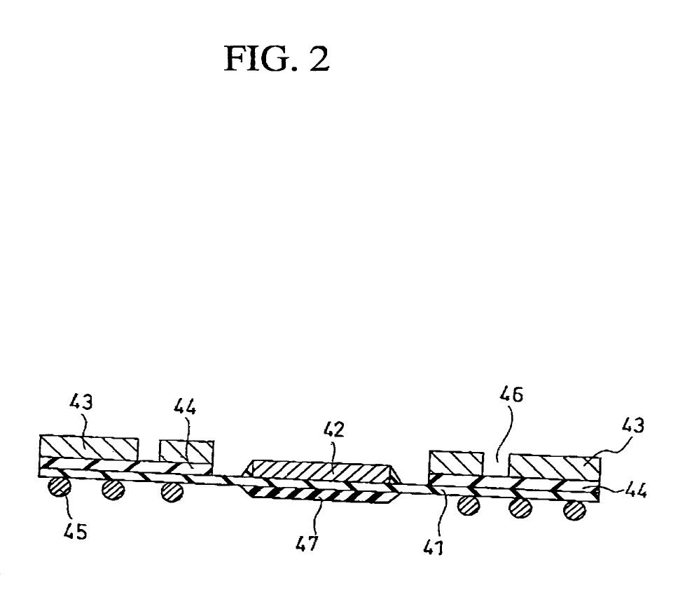

FIG. 3 is a fragmentary cross sectional elevation view illustrative of a novel film carrier semiconductor device for a metal double layered tape ball grid automated bonding film carrier tape in a first embodiment in accordance with the present invention.

FIG. 4 is a fragmentary cross sectional elevation view illustrative of a novel film carrier semiconductor device for a metal double layered tape ball grid automated bonding film carrier tape in a second embodiment in accordance with the present invention.

### DISCLOSURE OF THE INVENTION

The present invention provides a film carrier semiconductor device comprising: an insulative base film; inner leads provided on a first surface of the insulative base film; a signal interconnection pattern provided on the first surface of the insulative base film; a ground plane provided on a second surface of the insulative base film a conductive supporting plate fixed by a conductor to the first surface of the insulative base film, wherein the conductive supporting plate serves as a power voltage plane

It is preferable that the conductor comprises a conductive adhesive agent.

It is also preferable that the conductor comprises a conductive pin.

It is also preferable that the insulative base film comprises a polyimide film.

It is also preferable that solder resists are provided on the first and second surfaces of the insulative base film.

It is also preferable that the conductive supporting plate is further provided with a heat spreader.

### PREFERRED EMBODIMENT

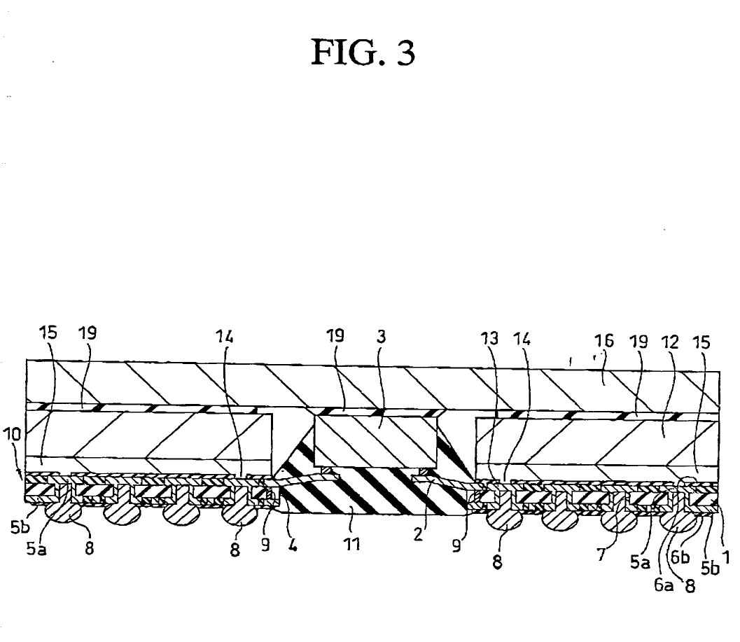

A first embodiment according to the present invention will be described in detail with reference to the drawings. FIG. 3 is a fragmentary cross sectional elevation view illustrative of a novel film carrier semiconductor device for a metal double layered tape ball grid automated bonding film carrier tape in a first embodiment in accordance with the present invention.

A plurality of inner leads 2 are formed on an insulative base film 1 made of a polyimide. The insulative base film 1 has a device hole 4. Inner portions of the inner leads 2 also extend over the device holes 4. Ends of the inner portions of the inner leads 2 are connected to electrodes provided on a surface of an LSI chip 3. The inner leads 2 are provided on a front surface of the insulative base film 1. On each of the front and back surfaces of the insulative base film 1, interconnection patterns 5a comprising a metal thin film and a ground plane 5b comprising a metal thin film are formed, around which solder resist films 6a and 6b made of a thermosetting resin such as a epoxy resin are formed.

Ones having a ground potential of the inner leads 2 are connected to the ground plane 5b through fine via holes 9 provided in the insulative base film 1 and positioned in the vicinity of the device hole 4. Other power source system inner leads and signal leads are connected through the interconnection pattern 5a to a land portion for an external terminal formation, wherein the land portion is provided On the surface, provided with the ground plane 5b, of the insulation base film 21, an outer lead bonding portion is formed for forming external terminals. The outer lead bonding portion is connected to the land portion through the through holes 7 provided in the insulative base film 1. The tape automated bonding tape or the tape ball grid array film carrier tape 10 comprises a metal double layered structure.

On the outer lead bonding portion of the insulative base film 1, power source system solder balls 8 are provided as external terminals for connection to the multilayer wiring board. The solder balls 8 are connected to the through holes 7. Further, the ground solder balls and signal solder balls are also provided.

The LSI chip 3 is mounted on the device hole 4 of the tape automated bonding tape 10, so that electrodes of the LSI chip 3 are connected to the inner leads 2. The LSI chip 3 and the tape automated bonding tape 10 are fixed to each other by potting an insulative resin 11 such as epoxy resin into the device hole 4. The solder resist 6a provided in the interconnection pattern 5a of the tape automated bonding tape 10 is provided with a solder resist opening 14 only on the land portion 13. A conductive stiffener 12 is bonded onto the solder resist 6a by a conductive adhesive agent 15, whereby the land portion 13 is electrically connected to the stiffener 12. A heat spreader 16 is bonded by an insulative adhesive agent 19 onto opposite side of the LSI chip 3 and the stiffener 12 to the insulative base film 1 for heat radiation. The heat spreader 16 comprises a plane plate with a high heat radiation property which is made of a metal such as Cu or Al or a ceramic material such as AlN or SiC. The conductive stiffener 12 bonded through the conductive adhesive agent 15 to the tape automated bonding tape 10, for which reason the conductive stiffener 12 serves as a power source plane having a power voltage.

The above conventional tape ball grid array package comprises a metal double layered structure comprising the ground plane and the interconnection pattern. By contrast, the novel tape ball grid array package comprises a metal triple layered structure comprising the ground plane 5b, the power source voltage plane and the interconnection pattern to reduce the inductance of the power source voltage interconnections and also improve the high speed performance of the semiconductor device.

It is possible as a modification to the above that the solder resist opening portion 14 is provided only on the lad portion 13 having the ground potential for the solder resist film 6a on the interconnection pattern 5, so that the stiffener 12 serves as a ground plane. A micro-strip line may be available which comprises a metal triple layered structure which comprises a ground plane, an interconnection pattern and a ground plane. This structure is selectable for the required device function.

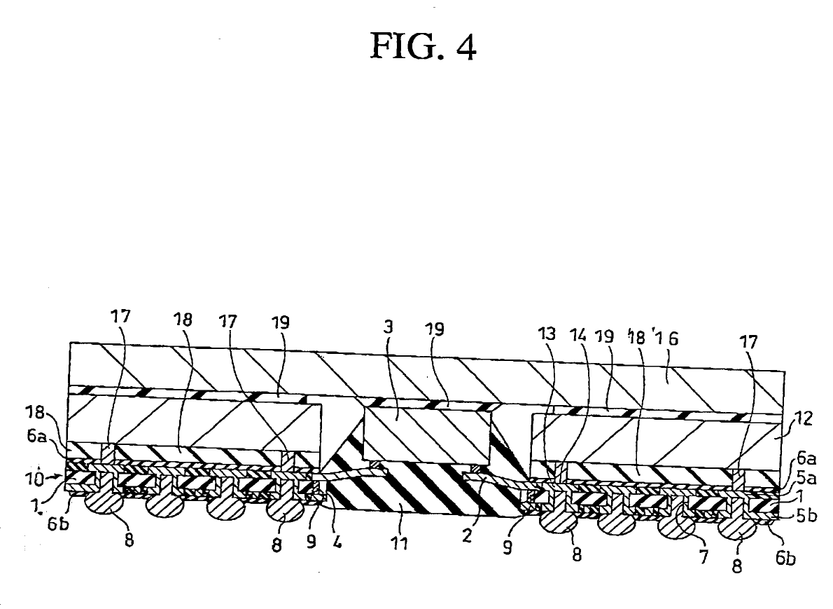

A second embodiment of the present invention will be described. FIG. 4 is a fragmentary cross sectional elevation view illustrative of a novel film carrier semiconductor device for a metal double layered tape ball grid automated bonding film carrier tape in a second embodiment in accordance with the present invention.

In this embodiment, in place of the conductive adhesive agent, metal pins are used for electrical connection between the land portion 13 and the stiffener 12. The following descriptions will focus on the difference of the second embodiment from the above first embodiment.

An interconnection pattern 5a is provided on one surface of a tape automated bonding tape 10. A ground plane 5b is provided on opposite surface of a tape automated bonding tape 10. Solder resists 6a and 6b are provided on the interconnection pattern 5a and the ground plane 5b respectively. The solder resist film 6a has a solder resist opening 14 only over the land portion 13 having the power source voltage. The land 13 and the conductive stiffener 12 are connected to each other by the metal pin 17 in the solder resist opening, wherein the metal pin 17 is solder-bonded to or metal-welded to the stiffener 12. The solder resist 6a and the stiffener 12 are bonded by the insulative adhesive agent 18, whilst all connecting or bonding parts except for the metal pins 17 are insulated.

The conductive pins 17 ensure electrical connection between the tape automated bonding tape 10 and the stiffener 12 to improve electrical resistance at the connecting portions and reliability thereof and also applicable to the highly reliable device.

Whereas modifications of the present invention will be apparent to a person having ordinary skill in the art, to which the invention pertains, it is to be understood that embodiments as shown and described by way of illustrations are by no means intended to be considered in a limiting sense.

Accordingly, it is to be intended to cover by claims all modifications which fall within the spirit and scope of the present invention.

What is claimed is:

1. A film carrier semiconductor device comprising:
an insulative base film;
inner leads provided on a first surface of said insulative base film;
a signal interconnection pattern provided on said first surface of said insulative base film;
a ground plane provided on a second surface of said insulative base film;
a conductive supporting plate fixed by a conductor to said first surface of said insulative base film,
wherein said conductive supporting plate serves as a power voltage plane.

2. The film carrier semiconductor device as claimed in claim 1, wherein said conductor comprises a conductive adhesive agent.

3. The film carrier semiconductor device as claimed in claim 1, wherein said conductor comprises a conductive pin.

4. The film carrier semiconductor device as claimed in claim 1, wherein said insulative base film comprises a polyimide film.

5. The film carrier semiconductor device as claimed in claim 1, wherein solder resists are provided on said first and second surfaces of said insulative base film.

6. The film carrier semiconductor device as claimed in claim 1, wherein said conductive supporting plate is further provided with a heat spreader.
